(19) United States
(12) Patent Application Publication
(10) Pub. No.: US 2020/0050990 A1
(43) Pub. Date: Feb. 13, 2020

(54) METHOD FOR ASSET MANAGEMENT OF SUBSTATION

(71) Applicant: HYOSUNG HEAVY INDUSTRIES CORPORATION, Seoul (KR)

(72) Inventors: Sung Jik Kim, Gimhae-si, Gyeongsangnam-do (KR); Jae Ryong JUNG, Gimhae-si, Gyeongsangnam-do (KR); Hwang Dong SEO, Gimhae-si, Gyeongsangnam-do (KR)

(21) Appl. No.: 16/608,062

(22) PCT Filed: Apr. 26, 2018
(86) PCT No.: PCT/KR2018/004869

§ 371 Date: Oct. 24, 2019

(30) Foreign Application Priority Data
Apr. 28, 2017 (KR) 10-2017-0055658

(51) Int. Cl. G06Q 10/06; G06F 17/18; G06Q 10/00; G01R 19/25

(52) U.S. Cl. CPC G06Q 10/06315; G06F 17/18; G01R 19/2513; G06Q 10/20; G06Q 10/067

(57) ABSTRACT

A method for asset management of a substation includes: generating a unique reliability model by each element of the substation by compensating a reference reliability model by the each element of the substation in comparison of reliability by the reference reliability model by the each substation type with reliability based on health index by the each element thereof generated based on state data and real-time monitoring data by the each element of the substation; assessing system reliability index and economic feasibility by each maintenance scenario based on a reference system reliability model for each candidate element subject to maintenance among the elements of the substation; selecting a maintenance scenario as a result of the health index and the unique reliability model by the each element of the substation, the system reliability index, and the economic feasibility; and updating the unique reliability model by the each element of the substation by executing maintenance.

### FIELD OF THE INVENTION

The present invention relates to a method for asset management of a substation; and more particularly to, the method for asset management of the substation of deriving an optimal management plan by each element of the substation depending on health index of the each element of the substation.

### BACKGROUND OF THE INVENTION

Among power systems, a transmission system or a distribution system has a substation to raise or reduce output of a generator or voltage of the system. In addition to a transformer for raising or reducing voltage, the substation includes devices or systems for centralizing or distributing power, those for controlling tidal current, or those for protecting and controlling its devices.

For example, in a gas circuit breaker used for a gas insulated switchgear or GIS, a gas pressure sensor for detecting gas pressure change, current and voltage detectors, etc. are installed while a transformer has a thermometer, a pressure gauge, a liquid measuring sensor, a current detector, etc. as sensors for detecting its state.

Those sensors are connected to a protective system, a measuring system, a controller, and a devices-monitoring system through cables which transmit electronic signals. Again, the protective system, the measuring system, the controller, and the devices-monitoring system are connected to a superior substation-monitoring controller through cables which transmit the electronic signals.

The substation has very complicated equipment to stably supply electricity which monitors operational state of a variety of devices such as a circuit breaker installed in the substation and also provides a monitoring system to detect a failure symptom in advance to prevent such failure or recover in rapid response to any incurred failure.

As it is difficult to identify accurate states of elements of the substation, the need for optimized techniques for asset management such as an element replacement cycle, and a maintenance plan is raised and a plan for solving such requirements is needed.

### DETAILED EXPLANATION OF THE INVENTION

### Objects of the Invention

An object of the present invention is to provide a method of compensating a reliability model by substation type based on health index of elements of a substation.

Another object of the present invention is to provide a method for asset management of a substation to draw an optimized unique reliability model by each element of the substation through a process of compensating a reference reliability model by the each substation type and an apparatus for executing this.

The other object of the present invention is to provide a method for asset management of a substation that satisfies clients' requested needs of equipment replacement cycles, maintenance plans, and asset management techniques and its apparatus for executing this.

The objects of the present invention are not limited to the aforementioned objects and other objects which have not been mentioned could be clearly understood by those skilled in the art from description below.

### Means of Solving the Problem

A method for asset management of a substation comprises steps of: determining whether to compensate a reliability model by each element of the substation by comparing reliability by a reference reliability model by each substation type with reliability based on health index by the each element thereof generated based on state data and real-time monitoring data by the each element of the substation; compensating the reference reliability model by the each substation type by using the health index by the each element of the substation as a result of the determination and generating a unique reliability model by the each element of the substation; assessing system reliability index and economic feasibility by each maintenance scenario based on a pre-generated reference system reliability model for each candidate element subject to maintenance among the elements of the substation; and updating the unique reliability model by the each element of the substation as a result of executing maintenance after selecting a maintenance scenario by the each candidate element subject to maintenance as a result of the health index by the each element of the substation, the unique reliability model by the each element of the substation, the system reliability index, and the economic feasibility; wherein the step of compensating the reference reliability model by the each substation type by the health index by the each element of the substation is to be capable of compensating the reference reliability model by the each substation type by applying the health index by the each element of the substation to the reference reliability model by the each substation type if the reference reliability model by the each substation type is different from reliability according to the health index by the each element of the substation.

Detailed matters of other example embodiments are included in detailed explanation and attached drawings.

### Effects of the Invention

The present invention has an advantage of being capable of properly compensating a reliability model by each substation type based on health index of each element of a substation.

The present invention has also an advantage of being capable of deriving an optimized unique reliability model by each element of the substation through a process of compensating the reference reliability model by the each substation type.

In addition, the present invention has an advantage of satisfying clients' requested needs of equipment replacement cycles, maintenance plans and asset management techniques.

### BRIEF DESCRIPTION OF THE DRAWINGS

FIG. 1 is a flowchart to explain a process of managing substation assets in accordance with one example embodiment of the present invention.

FIG. 2 is a flowchart minutely representing a method of compensating a reference reliability model by each substation type in accordance with the present invention.

FIG. 3 is a flowchart minutely representing a method of calculating calibration amount of a failure rate of the subsystem in FIG. 2.

FIG. 4 is a graph illustrating one example of a graph of average failure rate by subsystem.

FIG. 5 is a graph of average failure rate applied by calculating calibration amount of a failure rate of the subsystem if health index by subsystem in FIG. 4 is good.

FIG. 6 is a graph of average failure rate applied by calculating calibration amount of a failure rate of a subsystem if health index by subsystem in FIG. 4 is poor.

FIG. 7 is a block diagram to explain an internal structure of the apparatus for asset management of the substation in accordance with one example embodiment of the present invention.

FIG. 8 is a graph to explain a process of determining whether to compensate a reference reliability model by each substation type in accordance with one example embodiment of the present invention.

FIG. 9 is a graph to explain changes in reliability by each maintenance scenario by each element of the substation in accordance with one example embodiment of the present invention.

### DETAILED DESCRIPTION OF THE PREFERRED EMBODIMENTS

Detailed example embodiments to implement the present invention will be explained below by referring to attached drawings.

Advantages and/or characteristics of the present invention and a method for achieving them will be clarified by referring to example embodiments described in details with attached drawings. However, the present invention will not be limited to example embodiments below but will be implemented in a variety of forms. The example embodiments herein will complete the commencement of the present invention and will be provided to completely inform those skilled in the art of the scope of the present invention in the technical field to which the present invention belongs and the present invention is just defined by the scope of claims. Same reference signs indicate same components over the whole specification.

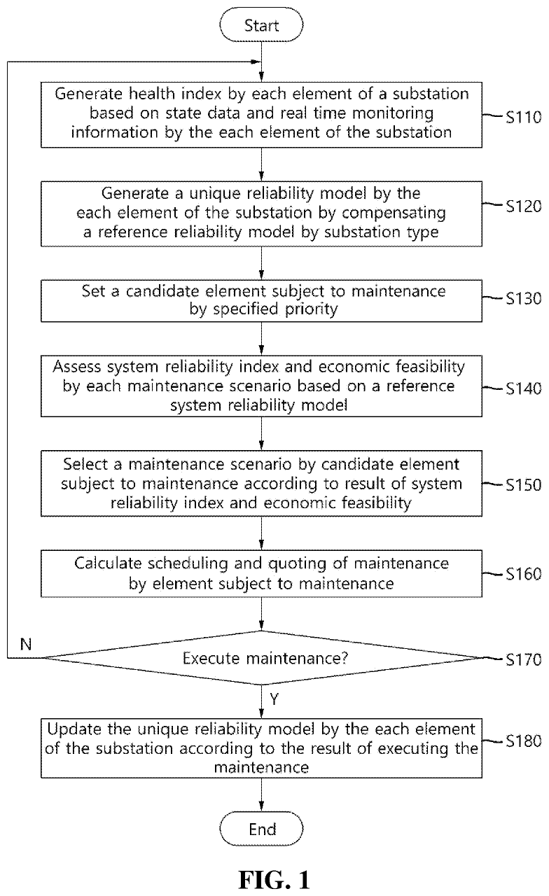

FIG. 1 is a flowchart to explain a process of managing substation assets in accordance with one example embodiment of the present invention.

By referring to FIG. 1, an apparatus for asset management of a substation generates health index by each element of the substation based on state data and real time monitoring data by each element of the substation at S110. At the time, the state data and the real time monitoring data by the each element of the substation include online, offline, and remote monitoring state data by the each element of the substation. The offline monitoring state data may include at least one of data on installation history, checkup history, failure history, an operating environment and operating history by each element of the substation.

In one example embodiment of S110, the apparatus for asset management of the substation may generate total score of, and actions against, technical risks depending on an operating environment, insulation deterioration, an electrical risk, a thermal risk, a chemical risk, a mechanical risk, airtightness performance, insulation performance, interrupting performance, and current-carrying performance by the each element of the substation.

For example, the apparatus for asset management of the substation may generate total score of, and actions against, technical risks depending on an operating environment, insulation deterioration, an electrical risk, a thermal risk, a chemical risk, and a mechanical risk of a transformer or TR by using information on a reference reliability model of the TR.

For another example, the apparatus for asset management of the substation may generate total score of, and actions against, technical risks depending on operating history data, airtightness performance, insulation performance, interrupting performance, and current-carrying performance of a gas insulated switchgear or GIS by using a reference reliability model of the GIS.

Next, the apparatus for asset management of the substation determines whether to compensate a reference reliability model by each substation type based on the reference reliability model by the each substation type and the health index by the each element of the substation.

Herein, the reference reliability model by the each substation type is the generated reference reliability model by the each substation type based on basic information on power equipment and information on failure history.

At the time, if the reliability according to the health index by the each element of the substation is identical to the reliability of the reference reliability model by the each substation type, the apparatus for asset management of the substation determines that the currently used reference reliability model by the each substation type is optimal, thereby not compensating the reference reliability model by the each substation type.

In addition, if the reliability according to the health index by the each element of the substation is different from the reliability of the reference reliability model by the each substation type, the apparatus for asset management of the substation generates a unique reliability model by the each element of the substation by compensating the reference reliability model by the each substation type at S120.

In short, if the reliability according to the health index by each element of the substation is different from the reliability of the reference reliability model by the each substation type, the apparatus for asset management of the substation determines that the currently used reference reliability model by the each substation type is not an optimal reference reliability model and compensates the reference reliability model by the each substation type by using the health index by the each element of the substation, thereby generating a unique reliability model by the each element of the substation.

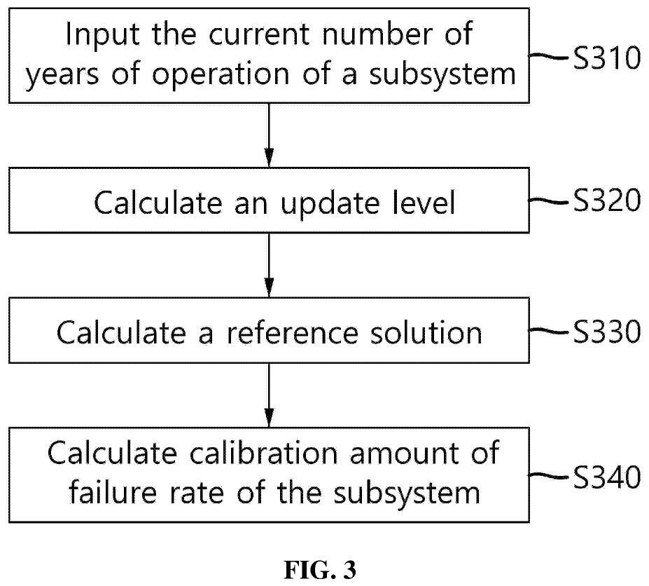

Herein, the step of compensating the reference reliability model by the substation type is performed by calculating an update level and a reference solution based on the current number of years of operation of a subsystem of the each element of the substation, and calculating calibration amount of failure rate of the subsystem based on them. Detailed explanation on this will be made later by referring to FIGS. 3 to 6.

Through the above-stated process of compensating the reference reliability model by the each substation type, the optimal reference reliability model by the each element of the substation may be drawn.

After that, the apparatus for asset management of the substation sets each candidate element subject to maintenance depending on a specified priority at S130. For example, if a specified priority of the apparatus for asset management of the substation is a failure rate, it is possible to set candidate elements with high failure rates subject to maintenance depending on the specified priority. In addition, other priorities may be applied under different situations.

Since then, the apparatus for asset management of the substation assesses system reliability index and economic feasibility by each maintenance scenario based on a pre-generated reference system reliability model for the each candidate element subject to maintenance among the elements of the substation at S140.

In accordance with one example embodiment of S140, the apparatus for asset management of the substation assesses power outage costs, value of lost load, sensitivity by element, current value, and future value by applying failure rate, failure recovery time, load by loading point, repair costs, recovery costs, target maintenance costs, interest rate, equipment sensitivity, and parent-child relationships between the elements of the substation to the pre-generated reference system reliability model.

Besides, the apparatus for asset management of the substation selects a maintenance scenario by the each candidate element subject to maintenance as the result of the system reliability index and the economic feasibility at S150.

In accordance with one example embodiment of S150, the apparatus for asset management of the substation draws and selects a maintenance scenario by candidate element subject to maintenance including a maintenance strategy method, costs, and priority, checkup cycle, estimated costs, checkup scheduling, and assumed maintenance effects, and expected replacement time by the each element of the substation depending on an output value for assessing reliability, an output value for technical assessment, and an output value for economic feasibility by maintenance scenario and cost items by maintenance checkup.

In another example embodiment of S150, the apparatus for asset management of the substation generates a maintenance scenario from an aspect of costs, a maintenance scenario from an aspect of reliability, optimal checkup, and a replacement plan according to information on a first result generated by combining the health index by the each element of the substation and the reference reliability model by the each substation type, a second result generated by combining the health index, system reliability index, and economic feasibility by each element of the substation and a third result by combining the information on the second result and a maintenance plan.

Next, the apparatus for asset management of the substation calculates scheduling and quoting of maintenance by each candidate element subject to maintenance at S160.

After the maintenance is executed by using the maintenance scenario by the each candidate element subject to maintenance at S170, the apparatus for asset management of the substation updates the unique reliability model by the each element of the substation as the result of executing the maintenance at S180.

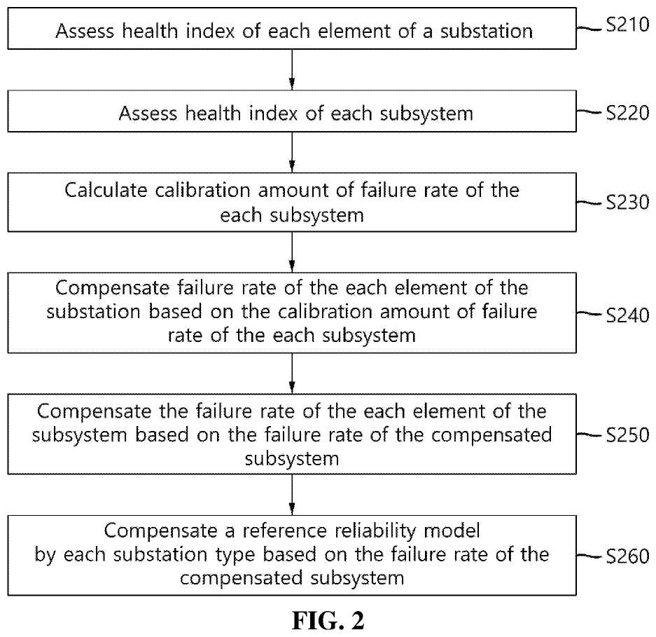

FIG. 2 is a flowchart minutely representing a method of compensating a reference reliability model by each substation type in accordance with the present invention.

As shown in FIG. 2, the method of compensating a reference reliability model by each substation type includes a step S210 of assessing health index of the each element of the substation; a step S220 of assessing health index of each subsystem of the each element of the substation; a step S230 of calculating calibration amount of failure rate of the subsystem; a step S240 of compensating the failure rate of the subsystem based on the calibration amount of the failure rate; a step S250 of compensating the failure rate of the each element of the substation based on the failure rate of the compensated subsystem; and a step S260 of compensating the reference reliability model by the substation type based on the compensated failure rate of the each element of the substation.

FIG. 3 is a flowchart minutely representing the method of calculating calibration amount of a failure rate of the subsystem in FIG. 2.

As seen in FIG. 3, the method of calculating calibration amount of a failure rate of a subsystem includes a step S310 of inputting current number of years of operation of the subsystem of the each element of the substation; a step S320 of calculating an update level of the subsystem; a step S330 of calculating a reference solution of the subsystem; and a step S340 of calculating calibration amount of failure rate of the subsystem based on the update level and the reference solution.

In other words, in the present invention, to compensate a reference reliability model by each substation type, the current number of years of operation of the subsystem of the each element of the substation is first inputted at S310.

Next, the update level of the subsystem in a form of quadratic equation is calculated based on the current number of years of operation of the subsystem thereof at S320. At the time, coefficients of the quadratic equation may be applied by using a pre-defined table such as an update level curve modification table by subsystem.

Since then, at the step S330 of calculating the reference solution of the subsystem, a reference failure time is obtained as a solution of the quadratic equation in the reference curve. At the time, coefficients of the quadratic equation may be applied by using the pre-defined table such as reference curve modification table by subsystem.

Next, at the step S340 of calculating the calibration amount of the failure rate of the subsystem based on the update level and the reference solution, the calibration amount of the failure rate of the subsystem is calculated by calculating difference between a reference failure time and the number of years of operation.

After that, the calculated calibration amount of the failure rate may be applied in any of methods of: moving a time axis of a failure rate (horizontal movement); increasing or reducing a failure rate (vertical movement); or changing tilt of a predicted failure rate after the present time.

In the present invention, there is an effect of being capable of properly compensating a reference reliability model by each substation type based on calibration of the failure rate in consideration of the current status by using the aforementioned methods.

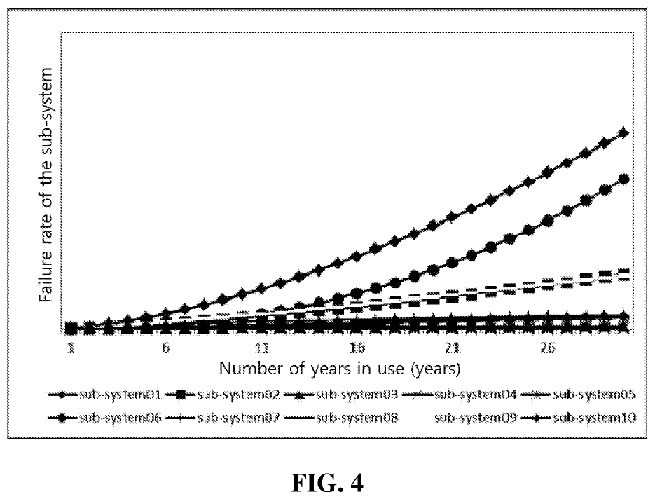

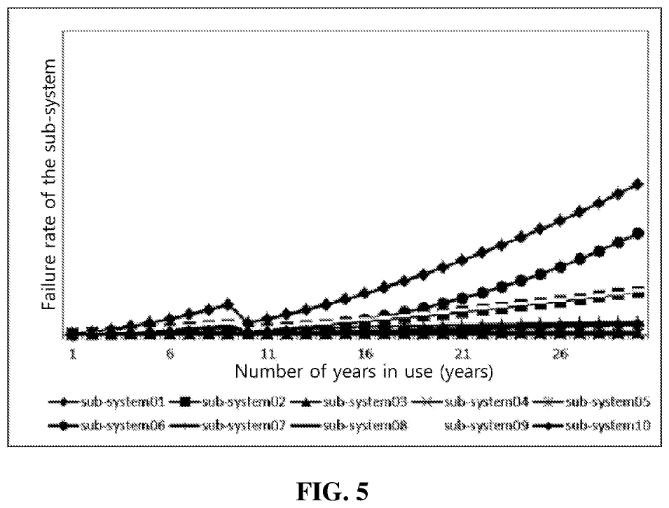

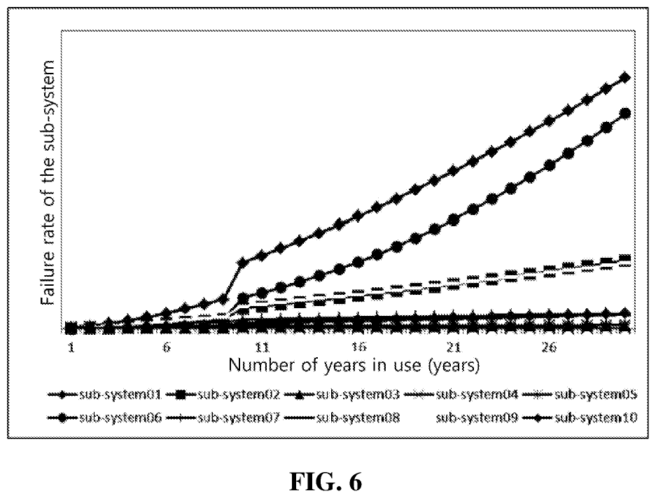

FIG. 4 is a graph illustrating one example of a graph of average failure rate by subsystem and FIG. 5 is a graph of average failure rate applied by calculating calibration amount of a failure rate of the subsystem if health index by subsystem in FIG. 4 is good. FIG. 6 is a graph of average failure rate applied by calculating calibration amount of a failure rate of a subsystem if health index by subsystem in FIG. 4 is poor.

As shown in FIG. 4, the traverse axis of the average failure rate graph of the GIS represents time and the vertical axis represents failure rate. Examples of graphs of calculating and applying calibration amount of the failure rate by the method of compensating a reference reliability model by substation type are FIGS. 5 and 6. Herein, the application of the calibration amount of the failure rate is under the method of moving the time axis of the failure rate (horizontal movement).

FIG. 5 is a graph of average failure rate applied by calculating calibration amount of a failure rate of the subsystem if the health index by subsystem in FIG. 4 is good. As shown in FIG. 5, if the health index by subsystem is good, the method of reducing the average failure rate is applied.

In other words, if the health index by subsystem is good, shifting time difference of the failure rate of the subsystem becomes negative (−), i.e., if the reference failure time is less than the current number of years of operation, a graph of average failure rate is moved left as much as shifting time difference of the failure rate to be displayed again.

In the present invention, this may reduce the average failure rate at a time-point of measurement and assign a low priority upon selection of the subject to maintenance to optimally calculate a maintenance scenario of the substation.

Meanwhile, FIG. 6 is a graph of average failure rate applied by calculating calibration amount of a failure rate of a subsystem if health index by subsystem in FIG. 4 is poor. As seen in FIG. 6, if the health index by subsystem is poor, the method of increasing the average failure rate is applied.

In other words, if the health index by subsystem is poor, shifting time difference of the failure rate of the subsystem becomes positive (+), i.e., if the reference failure time is greater than the current number of years of operation, a graph of average failure rate is moved right as much as shifting time difference of the failure rate to be displayed again.

In the present invention, this may increase the average failure rate at a time-point of measurement and assign a high priority upon selection of the subject to maintenance to optimally calculate a maintenance scenario of the substation.

In the above cases, as a method applying calibration amount of a failure rate, the method of moving the time axis of the failure rate (horizontal movement) was applied but the method is not limited to this. As explained above, a method of increasing or reducing the failure rate (vertical movement) or a method of changing tilt of a predicted failure rate after the present time may be also applied.

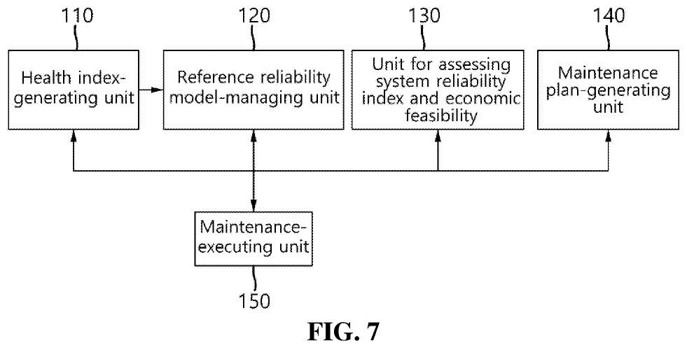

FIG. 7 is a block diagram to explain an internal structure of the apparatus for asset management of the substation in accordance with one example embodiment of the present invention.

By referring to FIG. 7, the apparatus for asset management of the substation includes a health index-generating unit 110, a reference reliability model-managing unit 120, a unit 130 for assessing system reliability index and economic feasibility, a maintenance plan-generating unit 140, and a maintenance-executing unit 150.

The health index-generating unit 110 generates health index by each element of the substation by using the state data and the real time monitoring data by the each element of the substation. At the time, the state data and the real time monitoring data by the each element of the substation includes online, offline, and remote monitoring state data by the each element of the substation. The offline monitoring state data may include at least one of data on installation history, checkup history, failure history, an operating environment, and operating history by the each element of the substation.

In accordance with one example embodiment of the present invention, the health index-generating unit 110 may generate total score of, and actions against, technical risks depending on an operating environment, insulation deterioration, an electrical risk, a thermal risk, a chemical risk and a mechanical risk, airtightness performance, insulation performance, interrupting performance, and current-carrying performance by the each element of the substation based on the state data and the real time monitoring data by the each element of the substation.

For example, the health index-generating unit 110 may generate total score of, and actions against, technical risks depending on an operating environment, insulation deterioration, an electrical risk, a thermal risk, a chemical risk, and a mechanical risk of a TR by using information on a reference reliability model of the TR.

For another example, the health index-generating unit 110 may generate total score of, and actions against, technical risks depending on operating history data, airtightness performance, insulation performance, interrupting performance, and current-carrying performance of a GIS by using a reference reliability model of the GIS.

The reference reliability model-managing unit 120 determines whether to compensate a reference reliability model by each substation type based on the reference reliability model by the each substation type and health index by the each element of the substation.

If the reliability according to the health index by the each element of the substation is identical to the reliability of the reference reliability model by the each substation type, the reference reliability model-managing unit 120 determines that the currently used reference reliability model by the each substation type is an optimal reference reliability model, thereby not compensating the reference reliability model by the each substation type.

In addition, if the reliability according to the health index by each element of the substation is different from the reliability of the reference reliability model by the each substation type, the reference reliability model-managing unit 120 compensates the reference reliability model by the each substation type, thereby generating a unique reliability model by each element of the substation.

In short, if the reliability according to the health index by each element of the substation is different from the reliability of the reference reliability model by the each substation type, the reference reliability model-managing unit 120 determines that the currently used reference reliability model by the each substation type is not an optimal reference reliability model, uses the health index by the each element of the substation, and compensates the reference reliability model by the each substation type, thereby generating a unique reliability model by the each element of the substation.

Herein, explanation on the method of compensating a reference reliability model by the substation type that has been already explained above is omitted.

As seen above, the present invention may optimize the unique reliability model by the each element of the substation by compensating the reference reliability model by the each substation type according to the health index by the each element of the substation, instead of continuously using the reference reliability model by the each substation type.

After setting each candidate element subject to maintenance among the elements of the substation depending on a specified priority, the unit 130 for assessing system reliability index and economic feasibility assesses system reliability index and economic feasibility by each maintenance scenario based on a pre-generated reference system reliability model for the each candidate element subject to maintenance.

After applying failure rate, failure recovery time, load by loading point, repair costs, recovery costs, target maintenance costs, interest rate, equipment sensitivity, and parent-child relationships between the elements of the substation to the pre-generated reference system reliability model, the unit 130 for assessing system reliability index and economic feasibility in accordance with one example embodiment of the present invention assesses the system reliability index and the economic feasibility by the each maintenance scenario by generating power outage costs, value of lost load, sensitivity by element, i.e., from economical and reliability aspects, a result of analysis of economic feasibility, i.e., current value, and future value.

The maintenance plan-generating unit 140 selects a maintenance scenario by the each candidate element subject to maintenance as the result of the health index by the each element of the substation, the reference reliability model by the each substation type, the system reliability index, and the economic feasibility.

In accordance with another example embodiment of the present invention, the maintenance plan-generating unit 140 draws and selects a maintenance scenario by the each candidate element subject to maintenance, including a maintenance strategy method, costs, and a priority by the each element of the substation, checkup cycle, estimated costs, checkup scheduling, and assumed maintenance effects by the each element of the substation, and expected replacement time by the each element of the substation depending on an output value for assessing reliability, an output value for technical assessment, and an output value for economic feasibility by the each maintenance scenario.

In accordance with another example embodiment of the present invention, the maintenance plan-generating unit 140 generates a maintenance scenario from an economical aspect, a maintenance scenario from a reliability aspect, optimal checkup, and a replacement plan according to information on a first result generated by combining the health index generated by the health index-generating unit 110 and the reference reliability model generated by the reference reliability model-managing unit 120, a second result generated by combining the health index generated by the health index-generating unit 110 and the system reliability index, and the economic feasibility generated by the unit 130 for assessing system reliability index and economic feasibility and a third result by combining the information on the second result and a maintenance plan generated by the maintenance plan-generating unit 140.

The maintenance-executing unit 150 checks whether to execute maintenance according to a maintenance scenario by a candidate element subject to maintenance selected by the maintenance plan-generating unit 140 and updates the unique reliability model by the each element of the substation as the result of executing the maintenance.

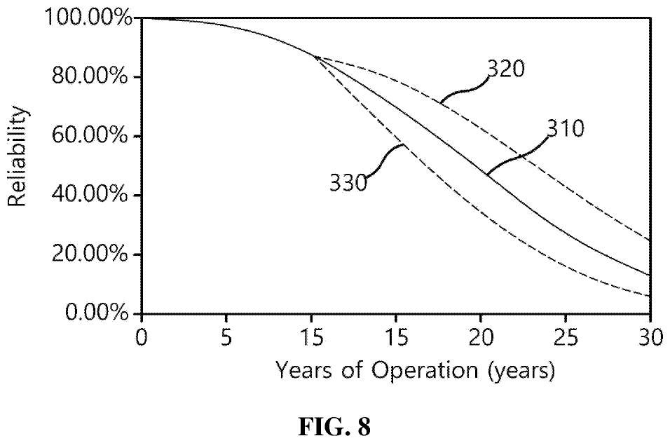

FIG. 8 is a graph to explain a process of determining whether to compensate a reference reliability model by each substation type in accordance with one example embodiment of the present invention.

By referring to FIG. 8, the apparatus for asset management of the substation determines whether to compensate a reference reliability model by each substation type by comparing reliability 310 of the reference reliability model by the each substation type with reliability 320, 330 according to the health index by the each element of the substation generated based on the state data and the real time monitoring data by the each element of the substation. Herein, the reference reliability model by the each substation type is a reference reliability model by the each substation type generated based on data on installation and checkup history, data on analysis of obsolete and removed items, and data on accelerated life tests by the each element of the substation.

Herein, a drawing reference number 320 represents that the reliability according to the health index by the each element of the substation is higher than the reliability 310 of the reference reliability model by the each substation type and a drawing reference number 330 represents that the reliability according to the health index by the each element of the substation is lower than the reliability 310 of the reference reliability model by the each substation type.

In accordance with one example embodiment of the present invention, if the reliability 310 of the reference reliability model by the each substation type is different from the reliability 320, 330 by the health index by the each element of the substation generated based on the state data and the real time monitoring data by the each element of the substation, the apparatus for asset management of the substation calculates a unique reliability model by each element of the substation by compensating the reference reliability model by the each substation type.

In other words, if the reliability 320, 330 according to the health index by the each element of the substation is different from the reliability 310 of the reference reliability model by the each substation type, the apparatus for asset management of the substation determines that the currently used reference reliability model by the each substation type is not an optimal reference reliability model and compensates the reference reliability model by the each substation type according to the health index by the each element of the substation, thereby calculating the unique reliability model by the each element of the substation.

Meanwhile, if the reliability according to the health index by the each element of the substation generated based on the state data and the real time monitoring data by the each element of the substation overlaps with the reliability 310 of the reference reliability model by the each substation type, the apparatus for asset management of the substation determines that the currently used reference reliability model by the each substation type is optimal, thereby not compensating the reference reliability model by the each substation type.

In the present invention, it is possible to draw an optimized unique reliability model by the each element of the substation through a process of compensating the reference reliability model by the each substation type as shown above.

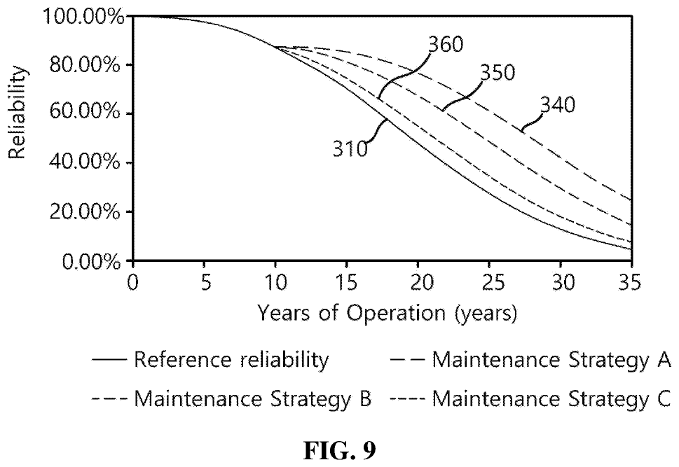

FIG. 9 is a graph to explain changes in reliability by each maintenance scenario by the each element of the substation in accordance with one example embodiment of the present invention.

In accordance with one example embodiment of the present invention, a standard on improving reliability by a maintenance method may be set differently. For example, the reliability would be possible to be set to 100% for replacement of an element as a maintenance method, 30% for precise inspection, and 15% for normal inspection but depending on history of actual maintenance carried out, the reliability may be differently set according to the maintenance under precise inspection and normal inspection.

In FIG. 9, it can be found that maintenance strategy A, as a maintenance scenario including the replacement of an element, shows the most greatly improved reliability (Drawing Graph No. 340) while maintenance strategy B as a precise inspection-centered maintenance scenario shows the moderately improved reliability (Drawing Graph No. 350).

Meanwhile, it can be found that maintenance strategy C as a maintenance scenario in center of normal inspection shows the least greatly improved reliability (Drawing Graph No. 360).

As shown above, the present invention has been explained by limited example embodiments and drawings but it is not limited to the example embodiments. Various changes and modifications may be derived from those skilled in the art. Accordingly, the invention must be identified by the claims of the present invention as described below and all variables and equivalents would appertain to the scope of the ideas of the present invention.

### REFERENCE NUMERALS

100: Apparatus for asset management of substation

110: Health index-generating unit

120: Reference reliability model-managing unit

130: Unit for assessing system reliability index and economic feasibility

140: Maintenance plan-generating unit

150: Maintenance-executing unit

### Industrial Availability

The present invention relates to a method for asset management of a substation and is available in a field of power equipment.

What is claimed is:

1. A method for asset management of a substation, comprising steps of:
determining whether to compensate a reliability model by each element of the substation by comparing reliability of a reference reliability model by each substation type and reliability according to health index by the each element thereof generated based on state data and real-time monitoring data by the each element of the substation;
compensating the reference reliability model by the each substation type and generating a unique reliability model by the each element of the substation by using the health index by the each element of the substation as a result of the determination;
assessing system reliability index and economic feasibility by each maintenance scenario based on a pre-generated reference system reliability model for each candidate element subject to maintenance among the elements of the substation; and
updating the unique reliability model by the each element of the substation as a result of executing maintenance after selecting a maintenance scenario by the each candidate element subject to maintenance as a result of assessing the health index by the each element of the substation, the unique reliability model by the each element of the substation, the system reliability index, and the economic feasibility;
wherein the step of compensating the reference reliability model by the each substation type by using the health index by the each element of the substation is to compensate the reference reliability model by the each substation type by applying the health index by the each element of the substation to the reference reliability model by the each substation type if reliability of the reference reliability model by the each substation type is different from reliability according to the health index by the each element of the substation.

2. The method of claim 1, wherein the step of compensating the reference reliability model by the each substation type by applying the health index by the each element of the substation to the reference reliability model by the each substation type includes steps of:
assessing the health index of the each element of the substation;
assessing the health index of each subsystem of the each element of the substation;
calculating calibration amount of failure rate of the subsystem;
compensating the failure rate of the subsystem based on the calibration amount of the failure rate;
compensating the failure rate of the each element of the substation based on the failure rate of the compensated subsystem; and
compensating the reference reliability model by the substation type based on the compensated failure rate of the each element of the substation.

3. The method of claim 1, wherein the reference reliability model by the each substation type is generated based on basic information on power equipment and information on failure history.

4. The method of claim 1, wherein the step of generating health index by each element of the substation based on state data and real-time monitoring data by the each element of the substation includes a step of generating the health index by each element of the substation by using online, offline, and remote monitoring state data by each element of the substation; and
wherein the offline monitoring state data include at least one of data on installation history, checkup history, failure history, an operating environment, and operating history by the each element of the substation.

5. The method of claim 1, wherein the step of generating health index by each element of the substation based on state data and real-time monitoring data by the each element of the substation includes a step of generating total score of, and actions against, technical risks depending on an operating environment, insulation deterioration, an electrical risk, a thermal risk, a chemical risk, a mechanical risk, airtightness performance, insulation performance, interrupting performance, and current-carrying performance by the each element of the substation.

6. The method of claim 2, wherein the step of calculating calibration amount of failure rate of the subsystem is to calculate an update level and a reference solution based on the current number of years of operation of the subsystem of the each element of the substation, and calculate calibration amount of failure rate of the subsystem based on the update level and the reference solution.

7. The method of one of claim 1, wherein the step of assessing system reliability index and economic feasibility by each maintenance scenario based on a pre-generated reference system reliability model for each candidate element subject to maintenance among the elements of the substation further includes a step of assessing power outage costs, value of lost load, sensitivity by element, current value, and future value by applying failure rate, failure recovery time, load by loading point, repair costs, recovery costs, target maintenance costs, interest rate, equipment sensitivity, and parent-child relationships between the elements of the substation to the reference system reliability model.

8. The method of claim 1, wherein the step of selecting a maintenance scenario by the each candidate element subject to maintenance as a result of the health index by the each element of the substation, the unique reliability model by the each element of the substation, the system reliability index, and the economic feasibility includes a step of deriving, and calculating a quote of, a maintenance scenario by candidate element subject to maintenance including a maintenance strategy method, costs, and priority by each element of the substation, checkup cycle, estimated costs, checkup scheduling, and assumed maintenance effects by each element thereof, and expected replacement time by each element thereof depending on an output value for assessing reliability, an output value for technical assessment, and an output value for economic feasibility by the maintenance scenario.

9. The method of claim 1, wherein the step of updating the unique reliability model by the each element of the substation as a result of the maintenance executed is to update the unique reliability model by the each element of the substation by applying improvement effects as the result of executing the maintenance.

10. The method of claim 1, wherein the step of assessing system reliability index and economic feasibility by each maintenance scenario based on a pre-generated reference system reliability model for each candidate element subject to maintenance among the elements of the substation includes a step of selecting a candidate element subject to maintenance among the elements of the substation depending on a predetermined priority.

11. The method of claim 6, wherein the update level is calculated in a form of quadratic equation and coefficients of the quadratic equation are applied by using a pre-defined table.

12. The method of claim 6, wherein the reference solution is a reference failure time as a solution of a quadratic equation in a reference curve and coefficients of the quadratic equation are applied by using a pre-defined table.

13. The method of claim 6, wherein the step of calculating calibration amount of failure rate of the subsystem based on the reference solution and the update level is to calculate calibration amount of failure rate of the subsystem by calculating difference between the reference failure time and the current number of years of operation.

14. The method of claim 2, wherein the step of compensating the failure rate of the subsystem based on the calibration amount of the failure rate is under one of methods of moving a time axis of a failure rate, increasing or reducing a failure rate, or changing tilt of a predicted failure rate after the present time.
